(19) United States
(12) Patent Application Publication
(10) Pub. No.: US 2009/0127647 A1
(43) Pub. Date: May 21, 2009

(54) SEMICONDUCTOR DEVICE, SOLID-STATE IMAGING DEVICE, AND METHOD OF MANUFACTURING SEMICONDUCTOR DEVICE

(76) Inventor: Akira NOGUCHI, Kurokawa-gun (JP)

Correspondence Address: BIRCH STEWART KOLASCH & BIRCH, PO BOX 747, FALLS CHURCH, VA, 22040-0747, US

(21) Appl. No.: 12/267,334

(22) Filed: Nov. 7, 2008

(30) Foreign Application Priority Data
Nov. 16, 2007 (JP) P2007-298178

(51) Int. Cl. H01L 31/00; H01L 21/00

(52) U.S. Cl. 257/440; 438/98; 257/E31.001

(57) ABSTRACT

A semiconductor device includes: a semiconductor substrate; an insulating layer; and a wiring layer that is a high-concentration impurity layer, in this order, wherein the semiconductor device further includes a contact portion that electrically connects the semiconductor substrate with the wiring layer, the contact portion is provided to pass through the wiring layer and the insulating layer to be brought into contact with a surface of the semiconductor substrate, and the contact portion has an impurity concentration lower than that in a connection region of the semiconductor substrate being in contact with the contact portion.

### CROSS-REFERENCE TO RELATED APPLICATIONS

This application claims the benefit of Japanese Patent Application JP 2007-298178, filed Nov. 16, 2007, the entire content of which is hereby incorporated by reference, the same as if set forth at length.

### FIELD OF THE INVENTION

The present invention relates to a semiconductor device, a solid-state imaging device, and a method of manufacturing a semiconductor device and in particular, to a contact structure that connects a semiconductor substrate with a wiring layer.

### BACKGROUND OF THE INVENTION

A solid-state imaging device in which a semiconductor substrate and a wiring portion formed on the semiconductor substrate are connected through a silicon-based conductive layer embedded in a contact hole and a method of manufacturing the same are known (for example, refer to JP-A-2006-108572).

### SUMMARY OF THE INVENTION

In the solid-state imaging device and the method of manufacturing the same disclosed in JP-A-2006-108572, a gate insulating layer is formed on a silicon substrate provided with a floating diffusion layer (floating diffusion region), a polycrystalline silicon layer to become a wiring portion is formed on the gate insulating layer, and then a contact hole is provided by etching the gate insulating layer using a photolithography method. Subsequently, a polycrystalline silicon layer to become a contact region is formed in the contact hole to connect the wiring portion with a floating diffusion region 28, that is, a semiconductor substrate. However, since each of the wiring portion and the contact region is a silicon-based conductive layer doped with low-concentration impurities, the electric resistance thereof is relatively high. Especially, the high electric resistance in the wiring portion has been a problem from a point of view of realizing a reduction in power consumption of a solid-state imaging device.

In order to reduce the electric resistance, it is effective to form a silicon-based conductive layer doped with high-concentration impurities as the polycrystalline silicon layer of the wiring portion. However, when a floating diffusion layer and the silicon-based conductive layer doped with high-concentration impurities are brought into contact with each other, the high-concentration impurities of the silicon-based conductive layer diffuse into the floating diffusion layer to change the impurity distribution. As a result, there has been a possibility that a diffusion potential profile will be changed to affect a charge storage characteristic.

The invention has been made in view of the above situation, and it is an object of the invention to provide a semiconductor device, a solid-state imaging device, and a method of manufacturing a semiconductor device capable of preventing a characteristic change of a semiconductor substrate caused by diffusion of impurities and reducing the electric resistance of a wiring portion.

The above object of the invention is achieved by the following configurations.

According to a first aspect of the invention, there is provided a semiconductor device including a contact portion that electrically connects a semiconductor substrate with a wiring layer which is a high-concentration impurity layer formed on a surface of the semiconductor substrate with at least an insulating layer interposed therebetween. The contact portion is formed to pass through the wiring layer and the insulating layer to be brought into contact with the surface of the semiconductor substrate and is formed with impurity concentration lower than that in a connection region of the semiconductor substrate being in contact with the contact portion.

In the semiconductor device configured as described above, the contact portion that connects the semiconductor substrate with the wiring layer which is a high-concentration impurity layer is formed as a conductive plug passing through the wiring layer and the insulating layer to be brought into contact with the semiconductor substrate. Since the impurity concentration of the contact portion which becomes a conductive plug is lower than that in the connection region of the semiconductor substrate being in contact with the conductive plug, impurities are not diffused from the conductive plug to the semiconductor substrate. Accordingly, since the impurity distribution of the semiconductor substrate is not affected by the conductive plug, a stable characteristic can be maintained. In addition, since the wiring layer is a high-concentration impurity layer, the semiconductor device with low electric resistance can be made. As a result, the power consumption can be reduced.

According to a second aspect of the invention, there is provided a solid-state imaging device including: a photoelectric conversion portion; a charge transfer portion that transfers a signal charge generated in the photoelectric conversion portion; and an output portion that generates an output signal on the basis of the signal charge transferred from the charge transfer portion. The output portion has a floating diffusion region for detecting the signal charge transferred from the charge transfer portion and an amplifier portion for amplifying the detected signal charge. A connection structure of the floating diffusion region and the amplifier portion is a structure of the semiconductor device according to the first aspect of the invention.

In the solid-state imaging device configured as described above, the floating diffusion region and a wiring layer, which is a high-concentration impurity layer connected to the amplifier portion, of the solid-state imaging device are connected to each other by a conductive plug with lower impurity concentration than that in the floating diffusion region. Accordingly, since diffusion of impurities to the floating diffusion region can be prevented while reducing the electric resistance of the wiring layer, the solid-state imaging device having stable performance can be obtained.

According to a third aspect of the invention, a method of manufacturing a semiconductor device having a contact portion that connects a semiconductor substrate with a wiring layer formed on a surface of the semiconductor substrate with at least an insulating layer interposed therebetween includes: forming a wiring layer, which is a high-concentration impurity layer, on the semiconductor substrate on which the insulating layer is formed; patterning the wiring layer and the insulating layer provided below the wiring layer to thereby open a part of the surface of the semiconductor substrate; forming a conductive layer doped with low-concentration impurities on the wiring layer; and patterning the conductive layer and the wiring layer.

In the manufacturing method configured as described above, the wiring layer which is a high-concentration impurity layer is formed on the semiconductor substrate on which the insulating layer is formed, the wiring layer and the insulating layer provided below the wiring layer are patterned to open a part of the surface of the semiconductor substrate, the conductive layer doped with low-concentration impurities is formed on the wiring layer, and the conductive layer and the wiring layer are patterned. Accordingly, impurities are not diffused from the conductive plug to the semiconductor substrate. This enables a stable characteristic to be maintained by making the impurity distribution of the semiconductor substrate fixed. In addition, since the wiring layer is a high-concentration impurity layer, the semiconductor device with low electric resistance can be made. As a result, the power consumption can be reduced.

According to the semiconductor device and the method of manufacturing a semiconductor device of the invention, a characteristic change of a semiconductor substrate caused by diffusion of impurities can be prevented and the electric resistance of the wiring portion can be reduced. In addition, when the wiring layer is used as a wiring line for connection with the floating diffusion region of the solid-state imaging device, the floating diffusion region is not affected by the diffusion of impurities and the charge storage characteristic becomes satisfactory.

### BRIEF DESCRIPTION OF THE DRAWINGS

FIG. 1 is a view illustrating view the layout configuration of an entire solid-state imaging device according to the invention.

FIG. 2 is a view illustrating the sectional structure near a floating diffusion region in the solid-state imaging device shown in FIG. 1.

FIG. 3 is a plan view near the floating diffusion region in the solid-state imaging device according to the present invention.

FIG. 4 is a cross-sectional view taken along the line P1-P2 of FIG. 3.

FIGS. 5A to 5E are explanatory views illustrating manufacturing processes for forming the contact structure near a floating diffusion region with the cross-sectional view taken along the line P1-P2 of FIG. 3.

### DESCRIPTION OF REFERENCE NUMERALS AND SIGNS

14: photoelectric conversion portion
16: charge read portion
22: output portion
23: amplifier portion
24: semiconductor substrate
28: floating diffusion region
42: insulating layer
44: wiring layer (high-concentration impurity layer)
48: silicon-based conductive layer
100: solid-state imaging device (semiconductor device)

### DETAILED DESCRIPTION OF THE INVENTION

Hereinafter, preferred embodiments of a semiconductor device, a solid-state imaging device, and a method of manufacturing a semiconductor device according to the invention will be described with reference to the accompanying drawings.

Here, an explanation will be made using a solid-state imaging device as an example of a semiconductor device.

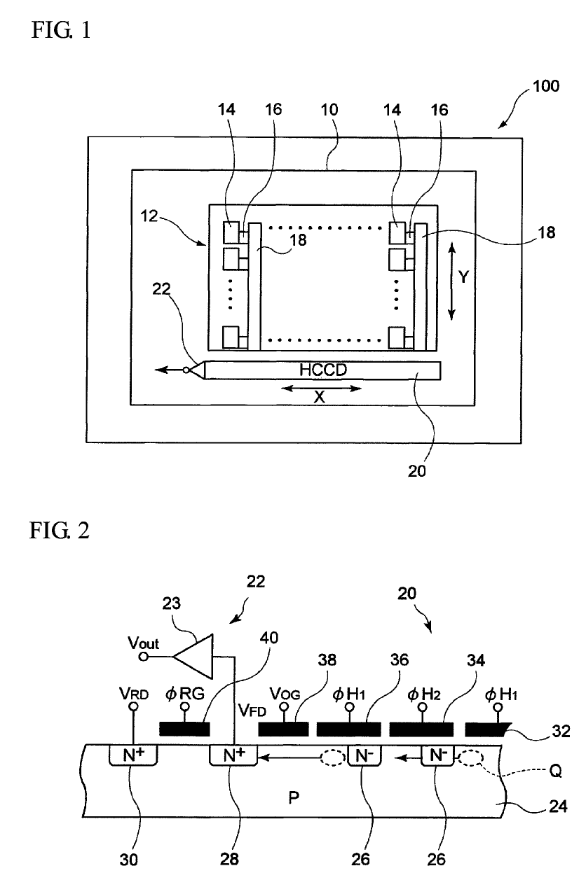

FIG. 1 is a plan view schematically illustrating a solid-state imaging device according to the invention, and FIG. 2 is a view illustrating the sectional structure near a floating diffusion region in the solid-state imaging device shown in FIG. 1.

As shown in FIG. 1, a pixel region 12 having a photoelectric conversion portion (photosensor) 14, a charge read portion 16, and a vertical charge transfer path 18, a horizontal charge transfer path (HCCD) 20, and an output portion 22 are provided in an imaging device forming region 10 of a CCD type solid-state imaging device 100.

As shown in FIG. 2, horizontal transfer electrodes 32, 34, and 36 are formed in the horizontal charge transfer path 20 and driving signal φH1 and φH2 are input to the horizontal charge transfer path 20. An output gate electrode 38 is disposed adjacent to the horizontal transfer electrode 36 at the final stage, and a predetermined DC voltage V_{OG} is continuously applied to the output gate electrode 38. Signal charges from the horizontal charge transfer path 20 are sequentially transferred to a floating diffusion region 28 where an N⁺ high-concentration impurity layer is formed.

A reset gate electrode 40 formed of an N⁺-type impurity layer is provided at a downstream side of charge transfer direction of the floating diffusion region 28, and a reset gate signal φRG for sweeping away signal charges accumulated in the floating diffusion region 28 is applied to the reset gate electrode 40. The signal charges of the floating diffusion region 28 are transferred to a reset drain 30 formed of an N⁺ impurity layer by a gate signal φRD. This reset drain (RD) 30 is fixed to a reset drain potential VRD. In addition, in FIG. 2, ‘Q’ shown in a state surrounded by a dotted line and the arrow shows how the electric charges move (are transferred). Since an electric potential of each of the signals φH1, φH2, φRG, VFD changes with time, the electric charge Q is transferred in a sequential manner.

In addition, an amplifier portion 23 for detecting and amplifying a signal charge of the floating diffusion region 28 is connected to the floating diffusion region 28. A source follower using a MOS transistor is typically used as the amplifier portion 23. Moreover, in the drawing, ‘VFD’ indicates the electric potential of the floating diffusion region 28.

Connection between the floating diffusion region 28 and the amplifier portion 23 will be described below in detail.

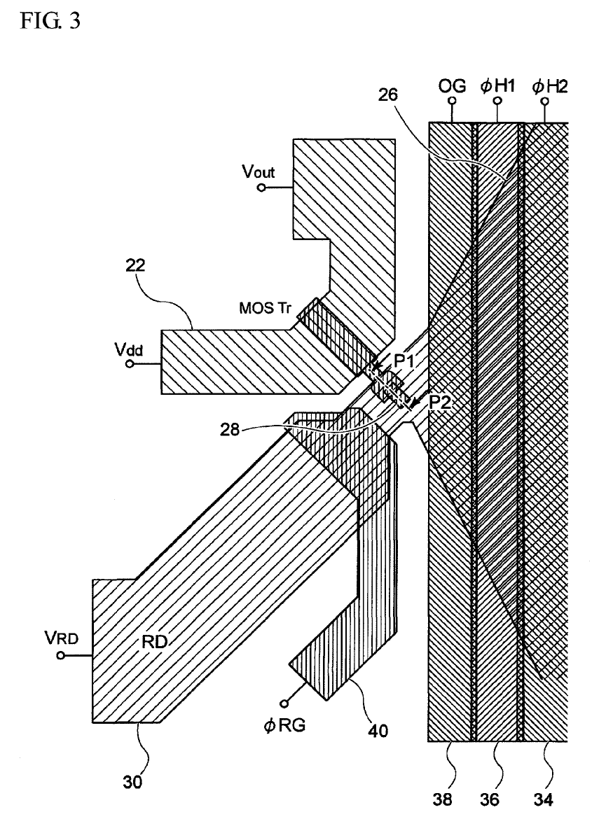

FIG. 3 is a plan view near the floating diffusion region shown in FIG. 2.

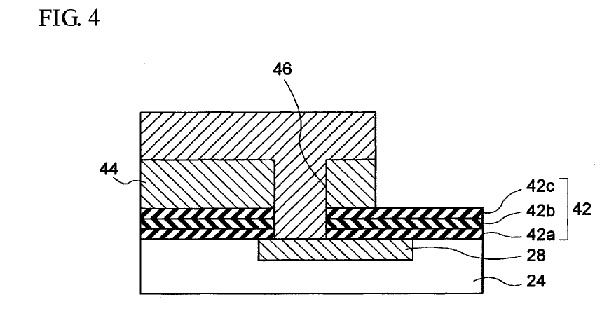

In FIG. 3, portions corresponding to those in FIG. 2 are denoted by the same reference numerals. As shown in a cross section taken along the line P1-P2 of FIG. 4, a gate insulating layer 42 having a silicon oxide layer 42a, a silicon nitride layer 42b, and a silicon oxide layer 42c on a semiconductor substrate 24, which is a silicon substrate, is formed and a wiring layer 44 formed of a high-concentration impurity layer is formed on the gate insulating layer 42. Then, a contact hole 46 passing through the gate insulating layer 42 and the wiring layer 44 is formed in a part of the floating diffusion region 28 so that the semiconductor substrate 24 is exposed. A silicon-based conductive layer 48 having lower impurity concentration than the floating diffusion region 28 is formed as a conductive plug, which is a contact portion, inside the contact hole 46 and the silicon-based conductive layer 48 other than the contact hole 46 is patterned similar to the wiring layer 44.

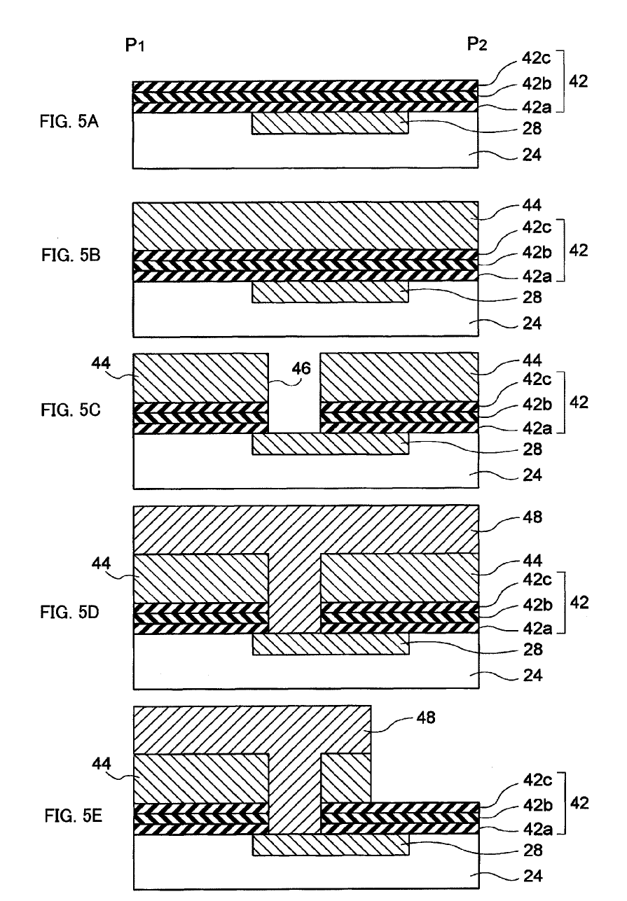

Next, a method of manufacturing the solid-state imaging device 100 with the above-described configuration will be described with reference to FIGS. 5A to 5E. In addition, a connection structure of the floating diffusion region 28 and the amplifier portion 23 will be described in detail and other portions will be omitted herein.

FIGS. 5A to 5E are explanatory views illustrating manufacturing processes for forming the contact structure in a floating diffusion region with the cross-sectional view taken along the line P1-P2 of FIG. 3.

First, as shown in FIG. 5A, the gate insulating layer 42 which is a layer with a three-layered structure (ONO film) including the silicon oxide layer 42a, the silicon nitride layer 42b, and the silicon oxide layer 42c, is formed on a surface of the semiconductor substrate 24 in which the floating diffusion region 28 is selectively formed. In addition, the gate insulating layer 42 is not limited to the layer with a three-layered structure but may be suitably changed. For example, the gate insulating layer 42 may be an SiOx layer partially. The impurity concentration of the floating diffusion region 28 is about 1.0×10²⁰ cm⁻³.

Then, as shown in FIG. 5B, the wiring layer 44 which is a silicon-based conductive layer doped with high-concentration impurities of impurity concentration of about 1.0×10²⁰ cm⁻³ is formed on the gate insulating layer 42 using a low pressure CVD method. Thereafter, as shown in FIG. 5C, a resist pattern is formed by photolithography and etched and the wiring layer 44 and the gate insulating layer 42 provided below the wiring layer 44 are patterned, thereby opening a contact hole 46 in a part of a surface of the semiconductor substrate 24.

Then, as shown in FIG. 5D, the silicon-based conductive layer 48 doped with low-concentration impurities of impurity concentration of about 1.0×10¹⁸ to 1.0×10¹⁹ cm⁻³ is formed on the wiring layer 44 using the low pressure CVD method, such that the contact hole 46 is embedded. The silicon-based conductive layer 48 becomes a conductive plug as a contact portion of the semiconductor substrate 24 and the wiring layer 44. Then, as shown in FIG. 5E, the silicon-based conductive layer 48 and the wiring layer 44 are patterned simultaneously to manufacture a semiconductor device (solid-state imaging device 100).

As described above, according to the semiconductor device and the method of manufacturing the same of the invention, the floating diffusion region 28 and the wiring layer 44, which is a high-concentration impurity layer connected to the amplifier portion 23, of the solid-state imaging device 100, are connected to each other by the silicon-based conductive layer (conductive plug) 48 having lower impurity concentration than the floating diffusion region 28. Accordingly, since diffusion of impurities from the silicon-based conductive layer 48 to the floating diffusion region 28 is prevented, the solid-state imaging device 100 with the stable performance where there is no change in charge storage characteristic caused by a change in electric potential distribution can be obtained.

Furthermore, in order to prevent the impurity diffusion, it is preferable that the high impurity concentration of the conductive plug 48 be lower than that in a region of the semiconductor substrate 24 connected to the conductive plug 48. However, the high impurity concentration of the conductive plug 48 is not particularly limited. In addition, since the impurity concentration of the wiring layer 44 is high, the electric resistance of the wiring layer 44 is low. As a result, the power consumption in the amplifier portion 23 can be reduced.

In addition, the semiconductor device according to the invention is not limited to the embodiment described above but may be suitably changed or modified. For example, although the silicon-based conductive layer doped with impurities beforehand is formed in the above embodiment, it is also possible to form a conductive layer first and then execute ion implantation of impurities without being limited to that described above. In addition, although the semiconductor device has been described as the solid-state imaging device, the invention may be applied to all kinds of semiconductor devices each having a plug portion that connects a semiconductor substrate and a wiring layer, and the same effects as in the present embodiment are obtained.

Although the invention has been described above in relation to preferred embodiments and modifications thereof, it will be understood by those skilled in the art that other variations and modifications can be effected in these preferred embodiments without departing from the scope and spirit of the invention.

What is claimed is:

1. A semiconductor device comprising:
a semiconductor substrate;
an insulating layer; and
a wiring layer that is a high-concentration impurity layer, in this order,
wherein the semiconductor device further comprises a contact portion that electrically connects the semiconductor substrate with the wiring layer,
the contact portion is provided to pass through the wiring layer and the insulating layer to be brought into contact with a surface of the semiconductor substrate, and
the contact portion has an impurity concentration lower than that in a connection region of the semiconductor substrate being in contact with the contact portion.

2. A solid-state imaging device comprising:
a photoelectric conversion portion;
a charge transfer portion that transfers a signal charge generated in the photoelectric conversion portion; and
an output portion that generates an output signal on the basis of the signal charge transferred from the charge transfer portion,
wherein the output portion comprises a floating diffusion region for detecting the signal charge transferred from the charge transfer portion and an amplifier portion for amplifying the detected signal charge, and
a connection structure of the floating diffusion region and the amplifier portion is a structure of the semiconductor device according to claim 1.

3. A method for manufacturing a semiconductor device having a contact portion that connects a semiconductor substrate with a wiring layer provided on a surface of the semiconductor substrate with at least an insulating layer interposed therebetween, the method comprising:
forming a wiring layer, which is a high-concentration impurity layer, on the semiconductor substrate on which the insulating layer is formed;
patterning the wiring layer and the insulating layer provided below the wiring layer to so as to open a part of the surface of the semiconductor substrate;
forming a conductive layer doped with low-concentration impurities on the wiring layer; and
patterning the conductive layer and the wiring layer.
